(19) United States
(12) Patent Application Publication
(10) Pub. No.: US 2013/0029465 A1
(43) Pub. Date: Jan. 31, 2013

(54) MANUFACTURING METHOD OF MEMORY STRUCTURE

(71) Applicants: TZUNG HAN LEE, TAIPEI CITY (TW); CHUNG-LIN HUANG, TAOYUAN COUNTY (TW); RON FU CHU, TAIPEI CITY (TW)

(72) Inventors: TZUNG HAN LEE, TAIPEI CITY (TW); CHUNG-LIN HUANG, TAOYUAN COUNTY (TW); RON FU CHU, TAIPEI CITY (TW)

(73) Assignee: INOTERA MEMORIES, INC., Taoyuan County (TW)

(21) Appl. No.: 13/240,011

(22) Filed: Sep. 22, 2011

(30) Foreign Application Priority Data
Jul. 29, 2011 (TW) 100126966

(51) Int. Cl. H01L 21/336

(52) U.S. Cl. 438/270; 257/E21.41

(57) ABSTRACT

The instant disclosure relates to a manufacturing method of memory structure for dynamic random-access memory (DRAM). The method includes the steps of: (a) providing a substrate having a plurality of parallel trenches formed on a planar surface thereof each defining a buried gate, where a first insulating layer is formed on the planar surface of the substrate; (b) forming a gate oxide layer on the surface of each trench that defines the buried gate; (c) disposing a metal filler on the gate oxide layer to fill each of the trenches; (d) removing the metal filler in the upper region of each trench to selectively expose the gate oxide layer; (e) implanting ions at an oblique angle toward the exposed portions of the gate oxide layer in each trench to respectively form a drain electrode and a source electrode in the substrate abreast the gate oxide layer.

### BACKGROUND OF THE INVENTION

1. Field of the Invention

The instant disclosure relates to a manufacturing method of memory structure; more particularly, to a manufacturing method of self-aligned dynamic random-access memory (DRAM).

2. Description of Related Art

To increase component density and improve overall performance of DRAM, continuous efforts are made by industrial manufacturers to reduce the sizes of capacitor and transistor for the DRAM. However, by decreasing the transistor size of the memory cell, the channel length (i.e., gate length) of the transistor decreases as well.

When the channel length is reduced, a short-channel effect often arises which negatively affects the performance of DRAM. In addition, the production of smaller transistor is a complex process requiring high manufacturing cost. Moreover, for existing manufacturing process, ions are implanted vertically into the substrate. Such technique lets the manufacturer looses control over the depths of the trenches and makes the production process more difficult. Therefore, the industrial manufacturers are eager to develop a manufacturing method that allows more control over the depths of the trenches to speed up the manufacturing process and lowers production costs.

To address the above issue, the inventors strive via industrial experience and academic research to present the instant disclosure, which can effectively improve the limitation described above.

### SUMMARY OF THE INVENTION

The instant disclosure provides a manufacturing method of memory structure for DRAM. The method comprises the steps of: (a) providing a substrate having a plurality of substantially parallel trenches formed on a substantially planar surface thereof each defining a buried gate, where a first insulating layer is formed on the planar surface of the substrate; (b) forming a gate oxide layer on the surface of each trench that defines the buried gate; (c) disposing a metal filler on the gate oxide layer to fill each of the trenches; (d) partially removing the metal filler in the upper region of each trench; and (e) implanting ions at an oblique angle toward the exposed portions of the gate oxide layer in each trench to respectively form a source electrode and a drain electrode in the substrate abreast the gate oxide layer and proximate the side walls that define each trench.

The instant disclosure possesses the following advantages. The sources and drains are formed in a self-aligned fashion by implanting the ions obliquely into the buried gates. Thereby, the photomasking process can be skipped to save fabrication cost. Secondly, the existing method implants the ions vertically toward the substrate. Whereas the ions are implanted obliquely for the instant disclosure, allowing the depths of the buried gates to be easily controlled.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is a flow chart showing the steps of a manufacturing method of memory structure of the instant disclosure.

FIG. 2 is a sectional view of step S1 for the manufacturing method of memory structure of the instant disclosure.

FIG. 3 is a sectional view of step S2 for the manufacturing method of memory structure of the instant disclosure.

FIG. 4 is a sectional view of step S3 for the manufacturing method of memory structure of the instant disclosure.

FIG. 5 is a sectional view of step S4 for the manufacturing method of memory structure of the instant disclosure.

FIG. 6 is a sectional view of step S5 for the manufacturing method of memory structure of the instant disclosure.

FIG. 7 is a sectional view of step S6 for the manufacturing method of memory structure of the instant disclosure.

### DETAILED DESCRIPTION OF PREFERRED EMBODIMENT

The instant disclosure provides a manufacturing method of memory structure. The presented method is explained through the manufacturing process of DRAM hereinbelow. The contents of the explanations are only for explanatory purposes rather than for restricting the instant disclosure. Likewise, the drawings shown in the figures are for helping the readers to understand the instant disclosure only, rather than restricting the actual dimensions in practice.

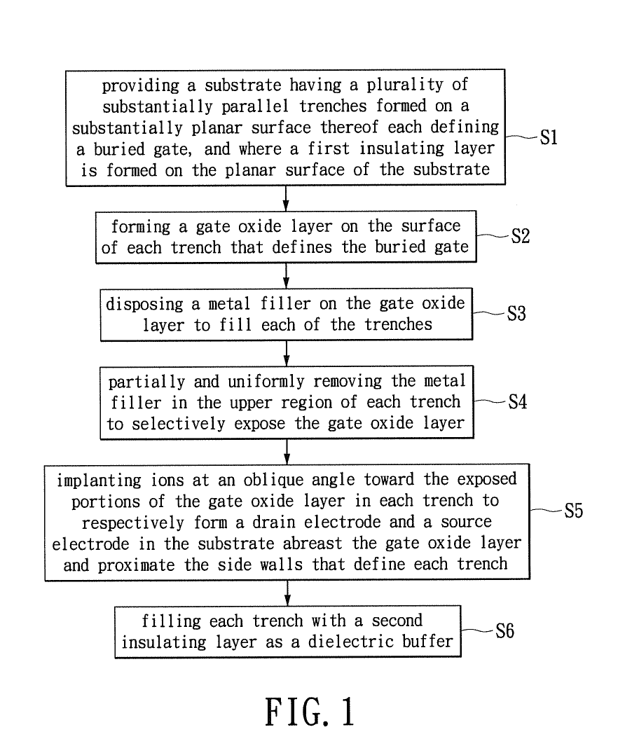

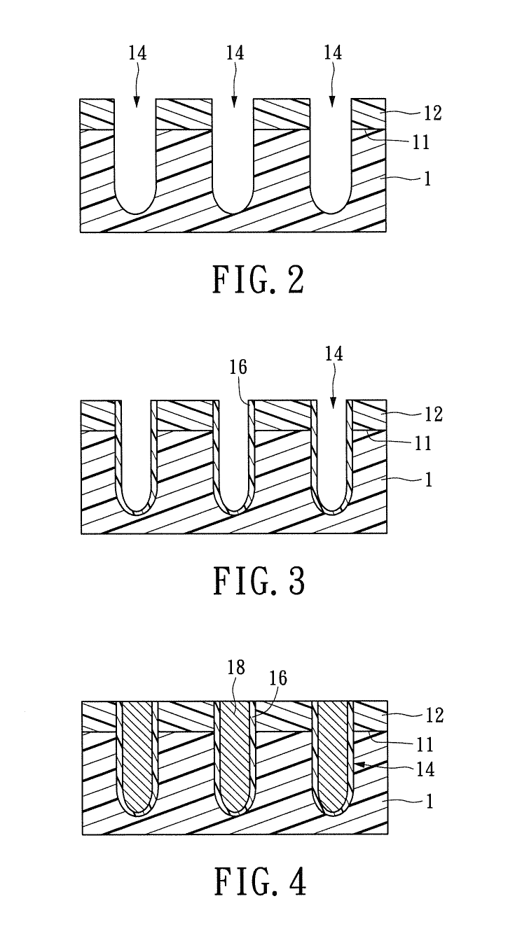

The aforementioned memory structure can be a DRAM. FIG. 1 is a flow chart showing the steps of the manufacturing method of the instant disclosure, and FIG. 2 is a sectional view of step S1. In step S1, a substrate 1 is provided having a substantially planar surface 11, where a plurality of substantially parallel trenches are formed thereon each defining a buried gate 14, and where a first insulating layer 12 is formed on the planar surface 11 of the substrate 1. For the instant embodiment, the substrate 1 is made of silicon. However, the material selection is not restricted. A person who is skilled in the art may arbitrarily choose the material for the substrate 1, and no further elaboration will be given herein.

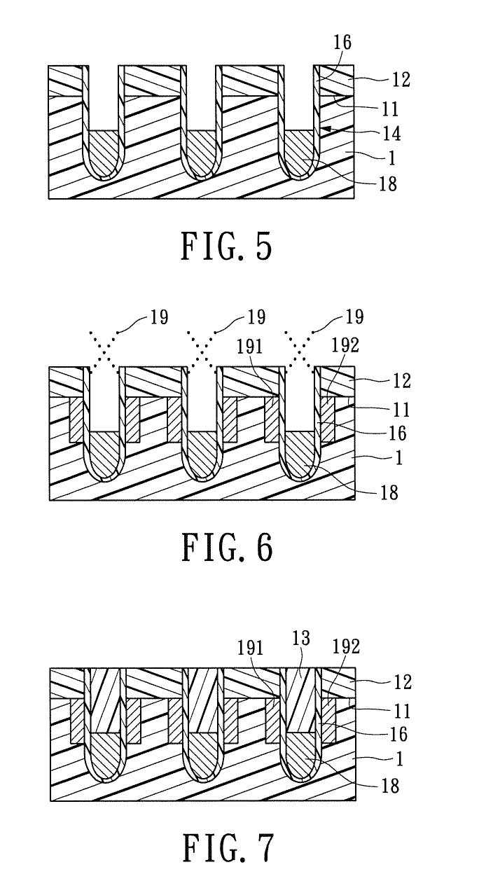

Next, please refer to FIG. 3 for step S2. In step S2, a gate oxide layer 16 is formed on the surface of each trench that defines the buried gate 14. Then, in step S3, which is shown in FIG. 4, a metal filler 18 is disposed on the gate oxide layer 16 to fill each of the trenches. The metal filler 18 is preferably tungsten. Then, step S4 is executed, which is illustrated by FIG. 5. In step S4, an etch back process is implemented to partially and uniformly remove the metal filler 18 in the upper region of each trench to selectively expose the gate oxide layer 16.

Then, please refer to FIG. 6 for step S5. With the substrate 1 and the first insulating layer 12 serving as a mask, a plurality of ions 19 are implanted at an oblique angle toward the exposed portions of the gate oxide layer 16 in each trench. The implantation results in the formation of a drain electrode 191 and a source electrode 192 in a self-aligned manner in the substrate 1 abreast the gate oxide layer and proximate the side walls that define each trench. To prevent the drain 191 and the source 192 from being too close to each other in creating short-channel effect, a lightly doped drain (LDD) is used to avoid the effects of hot carriers. More specifically, the implanting angle is preferably 7˜45 degrees, such that the drains 191 and the sources 192 may be formed at more favorable positions. The implanted species can be phosphorous or arsenic ions. However, the exact dopant ions to be used vary according to applications. Lastly, for step S6 as shown in FIG. 7, a second insulating layer 13 is deposited into each trench to fill up the void left by the aforementioned back etch process. The second insulating layer 13 serves as a dielectric buffer and is commonly a nitride layer. However, the material makeup of the second insulating layer 13 is not restricted. The second insulating layers 13 are planarized so as to be flushed with the first insulating layers 12.

Based on the above, the manufacturing method of the memory structure of the instant disclosure incorporates the self-aligned source and drain and light doped drain techniques, to prevent the occurrence of short-channel effect and improve the performance of the DRAM. In addition, the conventional photomasking step can be skipped to save production cost significantly. Moreover, the dopant ions are implanted obliquely toward the substrate, such that the manufacturer has better control over the depths of the buried gates and positions of the sources and drains.

The descriptions illustrated supra set forth simply the preferred embodiment of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A manufacturing method of memory structure, for dynamic random-access memory (DRAM), comprising the steps of:
(a) providing a substrate having a plurality of substantially parallel trenches formed on a substantially planar surface thereof each defining a buried gate, wherein a first insulating layer is formed on the planar surface of the substrate;
(b) forming a gate oxide layer on the surface of each trench that defines the buried gate;
(c) disposing a metal filler on the gate oxide layer to fill each of the trenches;
(d) partially and uniformly removing the metal filler in the upper region of each trench to selectively expose the gate oxide layer;
(e) implanting ions at an oblique angle toward the exposed portions of the gate oxide layer in each trench to respectively form a drain electrode and a source electrode in the substrate abreast the gate oxide layer and proximate the side walls that define each trench.

2. The manufacturing method of memory structure of claim 1, wherein the substrate is made of silicon.

3. The manufacturing method of memory structure of claim 2, wherein the metal filler is made of tungsten.

4. The manufacturing method of memory structure of claim 1, wherein a back etch technique is used to remove the metal filler in the upper region of each trench.

5. The manufacturing method of memory structure of claim 1, wherein the angle of implanting ions obliquely toward the gate oxide layers is preferably in the range of 7 to 45 degrees.

6. The manufacturing method of memory structure of claim 3, wherein the implanted ions are phosphorus or arsenic ions.

7. The manufacturing method of memory structure of claim 1, further comprises the following step after step (e):
(f) filling each trench with a second insulating layer as a dielectric buffer.

8. The manufacturing method of memory structure of claim 7, wherein step (f) further comprises:
(f1) planarizing each second insulating layer to be flushed with the first insulating layer.

9. The manufacturing method of memory structure of claim 8, wherein the second insulating layer is a nitride layer.
